(19) United States
(12) Patent Application Publication
(10) Pub. No.: US 2022/0254760 A1
(43) Pub. Date: Aug. 11, 2022

(54) METHODS, APPARATUSES, AND MATERIALS FOR PRODUCING MICRO-PIXELATED LEDS USING ADDITIVE MANUFACTURING

(71) Applicants: MASSACHUSETTS INSTITUTE OF TECHNOLOGY, Cambridge, MA (US); OSRAM OPTO SEMICONDUCTORS GMBH, Regensburg (DE)

(72) Inventors: Darshan KUNDALIYA, Middleton, MA (US); Xinhao LI, Cambridge, MA (US); Maria ANC, Groveland, MA (US); Nicholas FANG, Lexington, MA (US)

(21) Appl. No.: 17/623,795

(22) PCT Filed: Jul. 9, 2020
(86) PCT No.: PCT/US2020/041359

§ 371 Date: Dec. 29, 2021

Related U.S. Application Data
(60) Provisional application No. 62/872,231, filed on Jul. 9, 2019.

(51) Int. Cl. H01L 25/075; H01L 33/00; H01L 33/50; H01L 27/15

(52) U.S. Cl. CPC H01L 25/0753; H01L 33/005; B33Y 10/00; H01L 27/156; H01L 33/502

(57) ABSTRACT

Methods, systems, and materials for producing micro-pixelated LEDs capable of achieving a full-color spectrum through stereolithography techniques are provided. The techniques include depositing a photocurable nanophosphor ink composition onto a substrate, projecting a pattern onto the substrate and ink composition, and then curing at least a portion of the ink composition based on the projected pattern. The ink composition includes at least one photocurable polymer, a plurality of nanophosphors (e.g., QDs), and at least one light-scattering additive. The resulting cured ink composition and substrate component can be a pixelated LED that is configured to fully convert blue light-emitting pixels to red and green light-emitting pixels. Printing systems for performing these methods and producing these LEDs are also disclosed, as are various, non-limiting examples of ink composition formulations.

### CROSS REFERENCE TO RELATED APPLICATIONS

The present application claims priority to and the benefit of U.S. Provisional Application No. 62/872,231, filed Jul. 9, 2019, and titled “Methods, Apparatuses, and Materials for Producing Micro-Pixelated LEDS Using Additive Manufacturing,” the contents of which is incorporated herein by reference in its entirety.

### FIELD

The present disclosure relates to methods and apparatuses for printing micro-pixelated LEDs using additive manufacturing techniques, as well as exemplary formulations of ink compositions for use in printing such LEDs, and more particularly relates to the use of stereolithography techniques for wavelength converter printing that includes nanophosphor(s) on micro-pixelated LEDs.

### BACKGROUND

The significant interest in augmented reality (AR), virtual reality (VR) (e.g., near to eye), and wearable devices results in continued improvement in microdisplay technologies. The need of higher brightness and improved resolutions in display devices that are smaller in size, including being ultra-thin, and have an improved lifetime remains a design challenge. As shown in Table 1, various display technologies typically used in larger screens, such as Liquid Crystal Display (LCD), Organic Light emitting diodes (OLEDs), etc., have been developed in attempts to improve display performance in a more compact (e.g., thinner) manner.

TABLE 1
Comparison among various illumination technologies for microdisplays.

| | | | III-Nitride | | LASER BEAM |
|---|---|---|---|---|---|
| Technology | LCD | OLED | μLED | DLP | STEERING |
| Mechanism | Backlighting/LED | Self- | Self-emissive | Backlighting/LED | Backlighting/LD |
| | | emissive | | | |
| Luminous | Medium | Low | High | High | High |
| efficacy | | | | | |
| Luminance | 3000 cd/m²(full- | 1500 cd/m² | ~10\hat{ }5 cd/m² | ~1000 cd/m² | ~1000 cd/m² |
| | color) | (full-color) | (full-color) | (full-color | (full-color |
| | ~10⁴ cd/m² | ~10³ cd/m² | ~10⁷ cd/m² | | |
| | (green) | (yellow) | (blue/green) | | |
| Contrast | 200:1 | Very high | Very high | High | High |
| ratio | | >10000:1 | >10000:1 | | |
| Response | ms | μs | ns | ms | ms |
| time | | | | | |
| Operating | 0-60° C. requires | −50 to 70° C. | −100 to 120° C. | TBD | TBD |
| temp. | | | | | |
| Lifetime | Medium | Medium | Long | Medium (limited | Short (limited by |
| | | | | by MEMS) | LD) |
| Cost | Low | Low | Low | High | High |

Nevertheless, the need of increased brightness and resolution continues because technologies typically used in larger displays can end up wasting a significant amount of the generated light, due, for example, to filters used, and/or suffer lifetime issues. Still further, while progress has been made in fabricating monochrome pixelated LEDs, the ability to achieve direct emitting RGB (i.e., full-color) microdisplays that achieve desirable brightness, resolution, and device lifetime values remains a challenge, particularly in the arena of additive manufacturing (also referred to as three-dimensional printing).

Nanophosphors, such as quantum dots (QDs), can be used to provide luminescence. However, the incorporation of such technology into larger display and/or microdisplays is limited by the way by which such materials can be produced. Inkjet printing is a common manner for printing QDs solutions at least because inkjet printing is compatible with many colloidal and polymer inks. It can allow for tiny amounts of solution to be deposited in a desired area with some level of precision. Further, it can be a cost-effective technique to directly print patterns of different solutions on various substrates. However, the resulting resolution is not high enough for many uses in which high-resolution is paramount, such as in display technologies, due, at least in part, to the broadening or expansion of droplets that occurs once the ink deposited onto the substrates and the size of the nozzle aperture through which the ink is deposited. Additionally, the types of solvents that are compatible with inkjet printing can be such that they prevent the use of high concentrations of nanophosphors per milligram to allow for possible improved resolution.

Electrohydrodynamic jet printing is another technique that can be used for highly controlled spatial and volumetric deposition of liquids onto substrates. The technique uses a voltage difference between the printing nozzle and the substrates to create high-resolution patterns. While this technique can offer better printing resolution than inkjet printing, and can allow for printing to occur with multiple nozzles, the efficiency of the technique is low and may not be utilized for printing an area approximately greater than about 100 μm².

Conventional lithography (aka, photolithography) can allow for patterning polymers with feature sizes less than 10 μm. However, it is not trivial to spin cast QD in a transparent photoresist and pattern them via ultraviolet (UV) irradiation that induces photochemical reaction. Moreover, a conventional lithography technique can adversely affect the optical properties of the QDs. One of the other disadvantages of this technique, as well as with several other techniques based-on stamping, is the loss of QD materials due to the spin coating process involved.

Transfer printing of pixelated LEDs on a color converting membrane (e.g., II-VI MQW color-converting membrane) is another option with undesirable limitations. In such configurations, the blue micro-devices are bonded by capillary forces and retain their position through Van der Waals interaction at the interface. Materials such as a ZnCdSe/ZnCdMgSe membrane can be utilized for color conversion. This membrane is bonded directly to the sapphire window of the micro-LED through capillary bonding. Another transfer printing technique is intaglio. This technique utilizes an intaglio trench on a stamp to pick-up a QD layer with a light contact and slowly detach on the targeted substrates. To the extent these transfer techniques allow for desirable resolution, having multicolor pixels next to each other with individual pixel dimension less than about 10 μm would be a challenge. The yield using transfer techniques would be considerably low when envisioned in conjunction with above-described techniques for a large area transfer from a carrier substrate to an active device substrate. Further, various defects and damage to the converters can occur during a transfer process, for example, due to issues related to alignment, bonding, de-bonding, etc. As a result, transfer methods may be cost prohibitive in addition to potential unreliability. Still further, transfer techniques typically add extra process steps, which is generally not preferred because more steps typically means a higher likelihood for errors and higher costs.

In a non-printing technique, a quantum photonic imager (QPI) architecture based on quantum wells in which each pixel is comprised of a vertical stack of multiple LED layers and each layer produces light of a different primary color for a full-color display can be used. While this technique may be attractive and does not include a color conversion process, it is highly complex and likely suffers from luminous efficacy (brightness) for individual emitting primary colors. For example, green and red produced using QPI in comparison to that of color-converted micro-LEDs as provided for in the present disclosure are noticeably less bright.

In yet a further technique for achieving full-color pixelated LEDs, patterned polydimethylsiloxane (PDMS) mold filled with YAG:Ce phosphor slurry have been integrated onto micro-LEDs. These phosphor layers are approximately 60 μm to approximately 80 μm thick and create practical challenges for high contrast full-color or white color display with pixelated LEDs. A table of techniques that do not provide the desired combination of increased brightness, high-resolution, full-color spectrum of light conversion, longevity, and efficiency is provided below, identified as Table 2:

TABLE 2
Comparison of different printing methods for QDs.

| Method | Resolution | | Patterning area | | Advantages | Disadvantages |
|---|---|---|---|---|---|---|
| Screen printing | >20 | μm | >100 | cm² | Simple, possible for | Low resolution; not |
| | | | | | roll-to-roll process | suitable for microLEDs |
| Micro-Contact | Hundreds of nm | | >10 | cm² | Simple, versatile, | Pressing deformation, |
| printing or transfer | | | | | nondestructive | low efficiency; |
| or intaglio printing | | | | | | |
| Inkjet printing | Tens of μm | | >100 | cm² | High throughput | Low resolutions, low |
| | | | | | | accuracy of patterns, |
| | | | | | | solvents with high QDs |
| | | | | | | not possible? |
| Photolithography | Hundreds of nm | | Wafer size | | High throughput, | Radiation damages, |
| | | | | | large scale production | loss of materials; |
| | | | | | | Requires photomask |
| E-beam lithography | ~50 | nm | Several mm² | | High resolution | Low efficiency; |
| | | | | | | material damages |
| Nanoimprint | Tens of nm | | Wafer size | | High resolution; high | Heat or radiation |
| Lithography | | | | | throughput; | damage, substrate |
| | | | | | inexpensive | choices; direct printing? |
| | | | | | | Material choices |
| Dip-pen | Hundreds of nm | | >100 | μm² | High resolution; | Low efficiency |
| nanolithography | | | | | direct printing | |
| Laser ablation | ~1 | μm | >1 | mm² | Simple | Damages to materials; |
| | | | | | | loss of materials; |

Accordingly, there is a need for being able to manufacture wavelength converters onto micro-pixelated LEDs, and in particular such LEDs having individually addressable micro-pixels (e.g., controlled electrically), using additive manufacturing techniques that result in displays having increase brightness over their counterparts, high-resolution, and allow for a full-color spectrum of light conversion while maintaining or improving a lifetime of the printed converter/LED, while overcoming the many deficiencies of known printing techniques.

### SUMMARY

The present application discloses methods, systems, and materials for producing micro-pixelated LEDs capable of achieving a full-color spectrum through stereolithography techniques. The techniques can include depositing a photocurable nanophosphor ink composition onto a substrate, projecting a pattern onto the substrate and ink composition, and curing at least a portion of the ink composition based on the projected pattern. In accordance with the present disclosure, wavelength converters having QDs can be printed directly onto an LED substrate. The present application discloses wavelength converters that can contain one or more photo-curable ink compositions, as well as methods of printing, ink compositions, and micro-pixelated LEDs related to the same. A variety of photo-curable ink compositions are disclosed, such compositions including a polymer(s), one or more light-converting nano-particles, referred to herein as nanophosphors (e.g., QDs), and a light-scattering additive(s), which can increase blue absorption. Stereolithography techniques can be used to deposit the ink composition(s) onto a substrate surface, forming a micro-pixelated LED(s). The techniques disclosed herein can provide, among other things, for direct printing of wavelength converters onto a substrate with a high throughput, pixel-on-pixel printing with approximately 1 μm accuracy, and square shape pixels (a square is one exemplary embodiment of a pixel shape that can be achieved with the printing techniques described herein; other pixel shapes are within the scope of this disclosure). The wavelength converters can be configured in manner that allows for up to the full conversion of blue light into red and/or green colors. The converters can include nanophosphors (e.g. QDs) that are ultra-thin (approximately in the range of about 2 μm to about 10 μm) and can be directly printed onto pixelated LEDs.

One exemplary embodiment of a method of additively manufacturing an LED in accordance with the present disclosure includes depositing a photocurable nanophosphor ink composition onto at least one of a substrate or a cured photocurable nanophosphor ink composition, projecting a pattern onto at least one of the substrate, the cured photocurable nanophosphor ink composition, or the deposited photocurable nanophosphor ink composition, and curing at least a portion of the photocurable nanophosphor ink composition based on the projected pattern.

The method can further include depositing an additional photocurable nanophosphor ink composition onto at least one of the substrate or the cured photocurable nanophosphor ink composition, projecting a second pattern onto at least one of the substrate, the cured photocurable nanophosphor ink composition, or the deposited photocurable nanophosphor ink composition, and curing at least a portion of the additional photocurable nanophosphor ink composition based on the projected second pattern. The additional photocurable nanophosphor ink composition can be the same composition as the aforementioned photocurable nanophosphor ink composition that is deposited, or at least have the same formulation. Alternatively, it can be a different composition and/or formulation. Likewise, the second pattern that is projected can be the same pattern as the first pattern and projected in the same orientation, it can be the same pattern as the first pattern and projected in a different orientation, or it can be a different pattern. The method can further include actions of depositing projecting, and curing until a three-dimensional LED having nanophosphors disposed in it is produced. Like the additional photocurable nanophosphor ink composition, the action of depositing can be done with one or more further photocurable nanophosphor ink compositions that are the same composition and/or formulation as the first and/or the additional photocurable nanophosphor ink composition, or different from one or both such compositions. Likewise, the action of projecting can be done with one or more further patterns that are the same patterns and/or orientations as the first and/or second patterns, or different from one or both such patterns. Any combination of photocurable nanophosphor ink compositions and patterns can be used.

A resulting three-dimensional LED can be configured to fully convert blue light-emitting pixels to at least one of red light-emitting pixels or green light-emitting pixels. Pixels of the resulting three-dimensional LED can have a light-emitting pixel size that is approximately 25 μm or less, or is approximately 10 μm or less, or is approximately in the range of about 2 μm to about 5 μm. Other light-emitting pixel dimensions are also possible in view of the present disclosures. A distance between light-emitting pixels of the resulting three-dimensional LED can be approximately 5 μm or less. Such a distance can produce a high resolution. The resulting three-dimensional LED can include light-emitting pixels having a variety of shapes. For example, the resulting three-dimensional LED can include a plurality of square light-emitting pixels. The size, distance between, and shape of the light-emitting pixels can be uniform or non-uniform across an area or surface area of the resulting three-dimensional LED, up to and including the entire area or surface area of the resulting three-dimensional LED. A thickness of the resulting three-dimensional LED can be approximately in the range of about 2 μm to about 10 μm. Such a thickness for the LED can be referred to as ultrathin.

The method can further include washing away uncured photocurable nanophosphor ink composition prior to depositing additional photocurable nanophosphor ink composition. Alternatively, or additionally, the method can include coating a surface of the three-dimensional LED with a film having transparent properties and/or hazing properties. The coating action can occur after completing the action of depositing all additional photocurable nanophosphor ink compositions.

In some embodiments, the method can further include treating a surface of the substrate. Some non-limiting examples of such treatment can include at least one of chemically etching the surface, laser etching the surface, laser ablating the surface, or plasma activating the surface.

The substrate can be a pixelated LED substrate.

One exemplary embodiment of an additive manufacturing printing system in accordance with the present disclosure includes a dispenser, a projector, a light source, and a controller. The dispenser is configured to deposit a photocurable nanophosphor ink composition(s) onto at least one of a substrate or a cured photocurable nanophosphor ink composition(s). The projector is configured to project a pattern(s) onto at least one of the substrate, the cured photocurable nanophosphor ink composition(s), or the deposited photocurable nanophosphor ink composition(s). The light source is configured to cure at least a portion of the photocurable nanophosphor ink composition(s) based on the pattern(s) projected by the projector. The controller is configured to selectively operate each of the dispenser, the projector, and the light source to produce a three-dimensional LED that includes the substrate and the cured photocurable nanophosphor ink composition(s).

The controller can be configured to provide control to the various components of the system in a variety of manners. By way of non-limiting example, the controller can be configured to control the light source by controlling an exposure time and/or a power of the light source. In some embodiments, the system can also include a stage. The substrate onto which the dispenser deposits a photocurable nanophosphor ink composition and the projector possibly projects a pattern onto can be located on the stage. In some such embodiments, the controller can be further configured to operate movement of the stage, for example to locate the substrate at a desired location for at least one of receiving the photocurable nanophosphor ink composition(s) from the dispenser, receiving the projected pattern(s) from the projector, or receiving light(s) from the light source(s) to cure the photocurable nanophosphor ink composition(s). In some embodiments, the system can also include a pass-through optic(s). Such optic(s) can be configured to at least allow light(s) from the light source(s) to be passed therethrough, towards the substrate.

One exemplary LED in accordance with the present disclosure includes a pixelated LED and a wavelength converter. The pixelated LED includes a plurality of individually addressable pixels that are configured to be controlled electrically for light emission. The wavelength converter is deposited onto the pixelated LED and includes a plurality of nanophosphors. Further, the wavelength converter is configured to fully convert blue light-emitting pixels of the pixelated LED to at least one of red light-emitting pixels or green light-emitting pixels.

The pixelated LED can have light-emitting pixels of a variety of sizes. For example, light-emitting pixels of the pixelated LED can have a size that is approximately 25 μm or less, approximately 10 μm or less, or approximately in the range of about 2 μm to about 5 μm. Other light-emitting pixel dimensions are also possible in view of the present disclosures. A distance between light-emitting pixels of the pixelated LED can be approximately 5 μm or less. Such a distance can produce a high resolution. The pixelated LED can include light-emitting pixels having a variety of shapes. For example, the pixelated LED can include a plurality of square light-emitting pixels. The size, distance between, and shape of the light-emitting pixels can be uniform or non-uniform across an area or surface area of the pixelated LED, up to and including the entire area or surface area of the pixelated LED. A thickness of the pixelated LED in combination with the wavelength converter can be approximately in the range of about 2 μm to about 10 μm. Such a thickness for the LED can be referred to as ultrathin.

In some embodiments, the LED can include a coating that is disposed over a surface of the wavelength converter. The coating can include, for example, at least one of a transparent film and/or a hazing film. Alternatively, or additionally, a surface of the pixelated LED can include one or more etchings (or equivalents) formed in the surface.

An exemplary embodiment of a photocurable ink composition in accordance with the present disclosure includes one or more photocurable polymers, a plurality of nanophosphors, and one or more light-scattering additives. The plurality of nanophosphors is disposed within and/or on the one or more photocurable polymers. The one or more light-scattering additives are disposed within and/or on the one or more photocurable polymers as well. Further, the one or more light-scattering additives are configured to increase absorption of blue light.

An index of refraction of the photocurable ink composition can be approximately greater than about 1.35, or more particularly it can be approximately in the range of about 1.35 to about 2.2. The composition can be configured such that it does not undergo phase separation during a photopolymerization process. A concentration of the plurality of photopolymers can be approximately in the range of about 25 mg/mL to about 50 mg/mL. The plurality of nanophosphors can include QDs. In some such embodiments, the QDs can include colloidal QDs. The one or more light-scatting additives can include at least one of transparent oxides (e.g., TiO₂, ZrO₂, SiO₂), alumina (i.e., Al₂O₃), undoped YAG, or BaSO₄. A person skilled in the art will recognize that alumna, undoped YAG, and BaSO₄ can likewise be considered to be transparent oxides.

### BRIEF DESCRIPTION OF DRAWINGS

This disclosure will be more fully understood from the following detailed description taken in conjunction with the accompanying drawings, in which:

FIG. 1 is a schematic illustration of one embodiment of an additive manufacturing printing system;

FIG. 2 is an image of a of one embodiment of a projected light pattern that can be projected by the system of FIG. 1;

FIG. 3 is a side perspective view of one embodiment of an additive manufacturing printing system based on the schematic illustration of the printing system of FIG. 1;

FIG. 4 is a side perspective view of another embodiment of an additive manufacturing printing system based on the schematic illustration of the printing system of FIG. 1;

FIG. 5 schematically illustrates steps of two prior art methods for printing and transferring an array onto a substrate;

FIG. 6 illustrates one embodiment of a printed array printed in accordance with the methods of FIG. 5;

FIG. 7 illustrates further embodiments of printed arrays printed in accordance with the methods of FIG. 5;

FIG. 8 is graph of a cross-section profile of a layer printed in accordance with the methods of FIG. 5;

FIG. 9 illustrates an embodiment of a printed array printed in accordance with one of the methods of FIG. 5;

FIG. 10 illustrates an embodiment of a printed array printed in accordance with the other of the methods of FIG. 5;

FIG. 11 illustrates a micro-LED with QD dots from the print array of FIG. 10;

FIG. 12 illustrates the micro-LED of FIG. 11 through a filter;

FIG. 13 is a perspective view of one exemplary embodiment of an additive manufacturing printing system;

FIG. 14 is a perspective view of a printing apparatus of the system of FIG. 13;

FIG. 15 is a perspective view of another exemplary embodiment of an additive manufacturing printing system;

FIG. 16 is a perspective view of an inverted microscope portion of the system of FIG. 15;

FIG. 17 is a graph illustrating an absorptance and emission spectra of QDs

FIG. 18 illustrates one embodiment of a printing result from the system of FIG. 13, using multiple images to illustrate aspects of the printing result, and one embodiment of a printing result from the system of FIG. 15, using multiple images to illustrate aspects of the printing result;

FIG. 19 illustrates one exemplary embodiment of a full-color conversion micro LED printed in accordance with the present disclosure;

FIG. 20 illustrates a cross-sectional profile of two exemplary embodiments of a pixel printed in accordance with the present disclosure;

FIG. 21 illustrates another exemplary embodiment of a full-color conversion micro-LED printed in accordance with the present disclosure;

FIG. 22 illustrates details of the micro-LED of FIG. 21;

FIG. 23 illustrates a cross-sectional profile of a pixel of the micro-LED of FIG. 21;

FIG. 24 illustrates yet another exemplary embodiment of a full-color conversion on a micro LED printed in accordance with the present disclosure; and

FIG. 25 is a graph showing a PL efficiency achieved in the embodiment of the micro LED of FIG. 24.

### DETAILED DESCRIPTION

Certain exemplary embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present disclosure is defined solely by the claims. The features illustrated or described in connection with one exemplary embodiment may be combined with the features of other embodiments. Such modifications and variations are intended to be included within the scope of the present disclosure.

To the extent that the present disclosure includes various terms for components and/or processes of the disclosed devices, systems, methods, and the like, one skilled in the art, in view of the claims, present disclosure, and knowledge of the skilled person, will understand such terms are merely examples of such components and/or processes, and other components, designs, processes, and/or actions are possible. Further, to the extent the present disclosure describes or claims something as being “first,” “second,” “additional,” etc., a person skilled in the art will recognize such references are made for convenience purposes, and that, unless indicated otherwise, any order can be used and a “second” or “additional” material or action may mimic the “first” or “original” material or action. By way of non-limiting example, in some instances the description and/or claims may refer to an additional ink composition and/or “one or more further ink compositions” (or variants thereof, e.g., photocurable nanophosphor ink compositions) being deposited, and such additional ink compositions may be the same formulation as any previously deposited ink composition(s), or it may be a different formulation(s). By way of further non-limiting example, in some instances the description and/or claims may refer to projecting “a second pattern” or “one or more further patterns” (or variants thereof), and such second and/or further patterns may be the same pattern(s) as the first pattern and/or other pattern(s) that was projected, or it may be a different pattern(s) and/or a different orientation(s) of the same or different pattern(s) that was previously used.

Still further, the present disclosure provides some illustrations and descriptions that includes prototypes, bench models, and or schematic illustrations of set-ups. A person skilled in the art will recognize how to rely upon the present disclosure to integrate the techniques, systems, devices, and methods provided for into a product, such as a consumer-ready, factory-ready, or lab-ready three-dimensional printer. Notably, the printing system illustrated in the present disclosure may be described as a prototype or bench model set-up. More particularly, and as described in further detail below, the printing system includes a digital micro mirrors array that acts as a dynamic mask to reflect UV patterns onto a photopolymer resin/QD mixture and cures it. Using the method, pixelated arrays of QD converters that emits full red or green color by absorbing blue radiation of pixelated InGaN LED are deposited. The method utilizes a UV DMD for and an external lens to increase printing resolution. Further, to assist in visibly aligning QD dots on the pixelated LED, an inverted microscope is used with an external lens system and an automated x-y stage so that the focal plane of projected pattern is tuned onto the focal plane of the microscope for direct UV patterning. A person skilled in the art will recognize how to rely upon the present disclosure to integrate the techniques, systems, devices, and methods provided for into a product, such as a consumer-ready, factory-ready, or lab-ready three-dimensional printer.

The present disclosure is generally directed to full-color conversion on a micro LED and methods, systems, and materials related to the same. The present application discloses wavelength converters that contain one or more photo-curable ink compositions, as well as methods and ink compositions related to the same. A variety of photo-curable ink compositions are disclosed, such compositions including a polymer(s), one or more light-converting nano-particles, referred to herein as nanophosphors (e.g., QDs), and a light-scattering additive(s), which can increase blue absorption. Stereolithography techniques can be used to deposit the ink composition(s) onto a substrate surface, forming a micro-pixelated LED(s). The wavelength converters are configured in manner that allows for up to the full conversion of blue light into red and/or green colors. The converters can include nanophosphors (e.g. QDs) that are ultra-thin (approximately in the range of about 2 μm to about 10 μm), that can be directly printed onto pixelated LEDs. As provided for herein, an ultra-thin layer is one that achieves a desirable ratio between a pixel width and a layer. Further, the resulting LEDs can have desirable ratios between the pixel width and printed height of the converter. While such ratios will depend, at least in part, on the absorption coefficient of the color converters, in some exemplary embodiments a ratio of pixel width to printed height of a converter can be approximately in the range of about 1000:1 to about 1:1, and in some instances can be approximately 100:1, and in still some other instances can be approximately 10:1.

More particularly, projection-based stereolithography techniques of the present disclosure can use the specially-formulated ink compositions provided for or derivable from the present disclosures and can deposit such compositions directly onto a pixelated LED substrate. UV light patterns can be reflected onto the ink compositions and the ink compositions can subsequently be cured. The resulting configuration is the deposition of pixelated nanophosphor converters that emit full red or green color by absorbing blue radiation of pixelated LEDs (e.g., Indium Gallim Nitride (InGaN) LEDs) onto which they are deposited. Prior to the present disclosure, techniques for formulating pixelated LEDs could not print nanophosphors (e.g. QDs) having the sizes and pitches provided for herein (approximately 25 μm or less, approximately 10 μm or less, approximately 5 μm or less, or approximately 2 μm) directly on a pixelated LEDs, especially with such LEDs having modified surfaces and ink formulations provided for in the present disclosure and/or by μ-stereolithography.

The resolution that results from the projection-based printing provided for in the present disclosure allows for a high-resolution wavelength converter, and thus high-resolution display. More particularly, the direct printing technique provided can maintain a distance between two pixels that is approximately less than about 5 μm, which results in high-resolution.

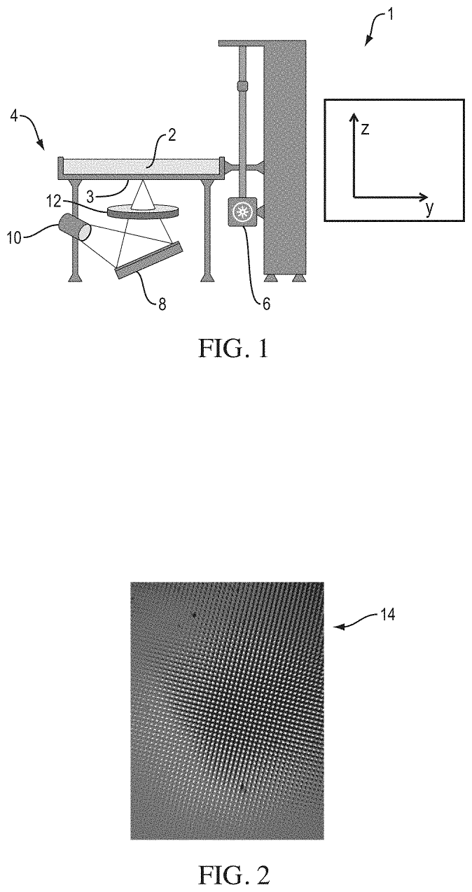

The projection-based methodology utilized in conjunction with ink compositions of the present disclosure can allow for printing of the ink composition, and thus the resulting wavelength converter, to occur directly on a functional device (e.g., an LED), which is superior to a “print and transfer” method in which a wavelength converter is printed onto a slide and subsequently transferred onto a functional device. To best understand the key aspects of the present disclosure, it is helpful to first understand a “print and transfer” method, which is described below with reference to FIGS. 1-12.

### Discussion of Previous “Print and Transfer” Methods, and Systems for Performing Such Methods

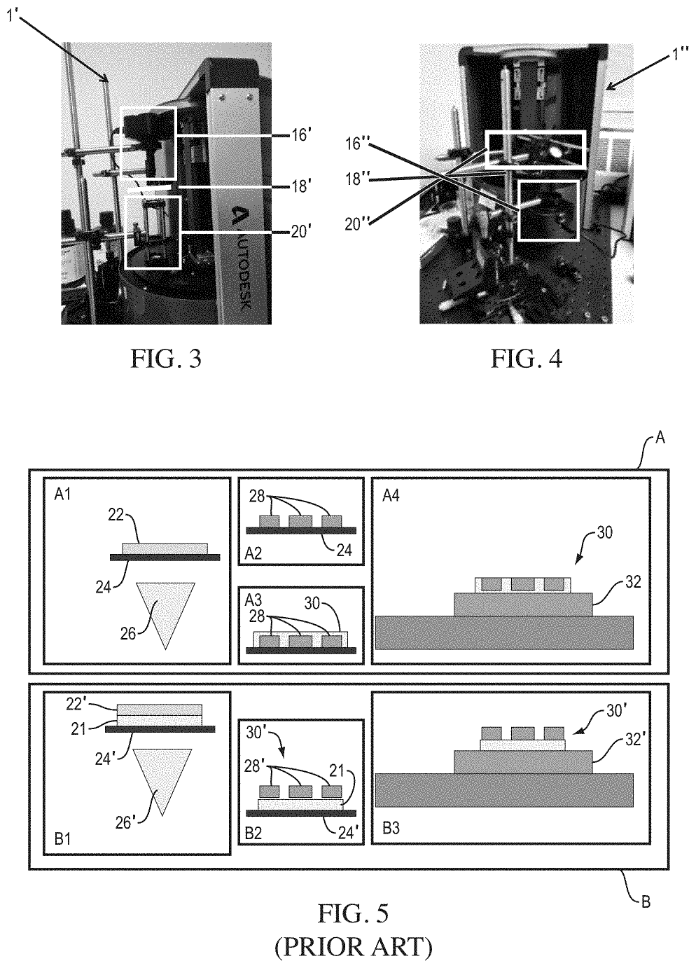

FIG. 1 illustrates a schematic illustration of an additive manufacturing printing system 1 that can be used to print a pattern with a photopolymer ink directly onto a glass side in accordance with known “print and transfer” methods. A photopolymer mixture 2, which, in some embodiments, can include QDs, can be deposited onto a glass slide 3 disposed on, coupled to, or otherwise associated with a stage 4. A motor 6 can be used to adjust the stage 4 along a vertical z-axis. A digital-mirror device (DMD) 8 can direct light (e.g., UV light) from a light source 10 through a lens 12 onto the glass slide 3. FIG. 2 illustrates one example of a projected UV light pattern 14 onto a focal plane (e.g., the stage 4). Portions of the photopolymer mixture 2 that are exposed to the projected light can be cured by the light. The perspective views of FIGS. 3 and 4 can be more accurately described as a “bottom-up” and “top-down” set-up or system 1′, 1″, respectively, which can be used to create a wavelength converter with the “print and transfer” method. The systems 1′ and 1″ are based upon an Ember 3D Printer from Autodesk, Inc. of San Rafael, Calif., which utilizes a UV projector from Texas Instruments Incorporated of Dallas, Tex., the relevant aspects of which are derivable from specifications and the like distributed with the printer and projector, are readily available to and understood by a person skilled in the art, and the contents of which are incorporated herein by reference. The bottom-up system 1′ of FIG. 3 can include a microscope 16′, a printing stage 18′, and a 2-lens system 20′, with the stage located above or proximal to the lens along the Z-axis such that the lens can project light from the “bottom up” onto the stage. The top-down system 1″ of FIG. 4 can include a microscope 16″, a printing stage 18″, and a 2-lens system 20″, with the stage located below or distal to the lens along the Z-axis such that the lens can project light from the “top down” onto the stage. The lens 12, 18′, 18″ of the systems 1, 1′, 1″ can, at least in part, dictate a size of a pixel in a pattern of projected light. For example, in some embodiments, a lens can be selected to reduce a pixel size to about 25 μm or about 15 μm. While the additive manufacturing printer systems 1, 1′, 1″ of FIGS. 1, 3, and 4 are illustrated and described relative to producing prior results, e.g., a QD array printed directly on a glass slide, these printer systems can be adapted for use in accordance with the printing techniques disclosed herein, for example, with the inclusion of an inverted microscope and other components described in detail below.

FIG. 5 pictorially illustrates steps of a two print and transfer method. More particularly, box A of FIG. 5 illustrates steps in a first example of a printing and template transfer procedure and box B of FIG. 5 illustrates steps in a second example of a printing and template transfer procedure.

The method can begin at A1 with an uncured photopolymer and QD composite 22 on a glass slide 24, which can be placed in a printing system or set-up such as those described above with reference to FIGS. 1-4. UV light can be projected onto the glass slide, as described above, such that portions 28 of the uncured polymer that are exposed to the UV light can be cured. As shown in A2, the uncured photopolymer 22 can be rinsed away to leave the cured portions 28 on the glass slide 24. A QD array 30 can be formed with a cured, clear photopolymer composite and the cured portions 28, illustrated in A3. The QD array can be stripped from the slide 24 and can be transferred onto a micro-LED chip 32. As shown in A4, the QD array can be bonded to the LED chip 32 using a variety of techniques known to those skilled in the art to bond items like a QD array to an LED chip.

In the second example of the printing and template transfer procedure, shown in box B, the method can begin at B2 with an uncured photopolymer and QD composite 22′ placed on a thin layer 21 of a cured clear photopolymer present on a glass slide 24′. A UV light 26′ can be projected onto the glass slide such that portions 28′ of the uncured photopolymer and QD composite 22′ that are exposed to the light can be cured onto the thin layer 21 to form a QD array 30′, illustrated in B2. The uncured portions of the photopolymer and QD composite 22′ can be rinsed away and the QD array 30′ can be stripped from the glass slide 24′ and transferred onto a micro LED chip 32′, as shown in B3.

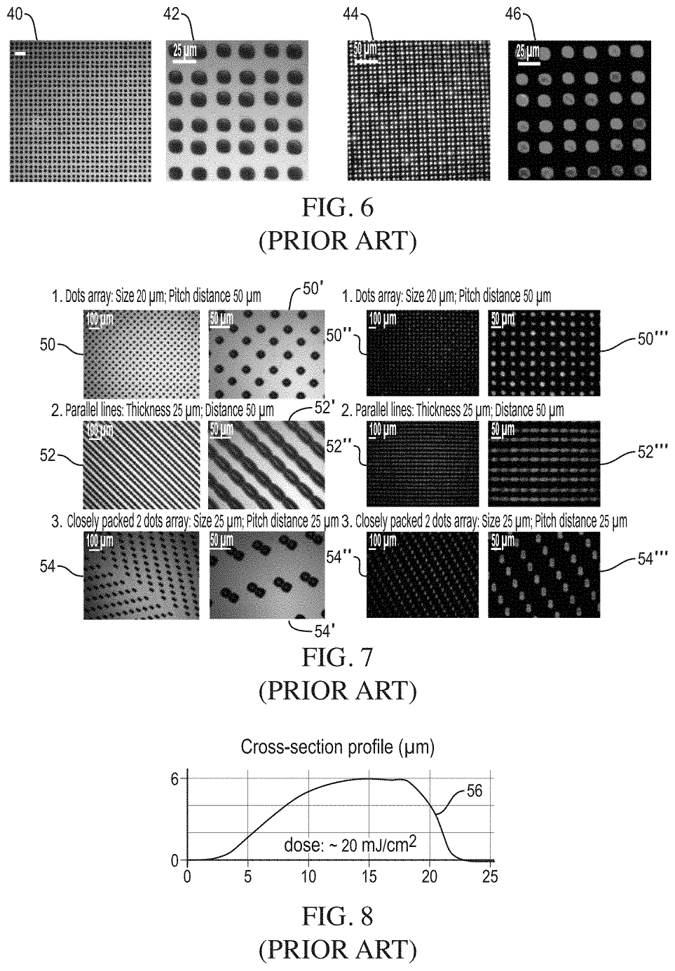

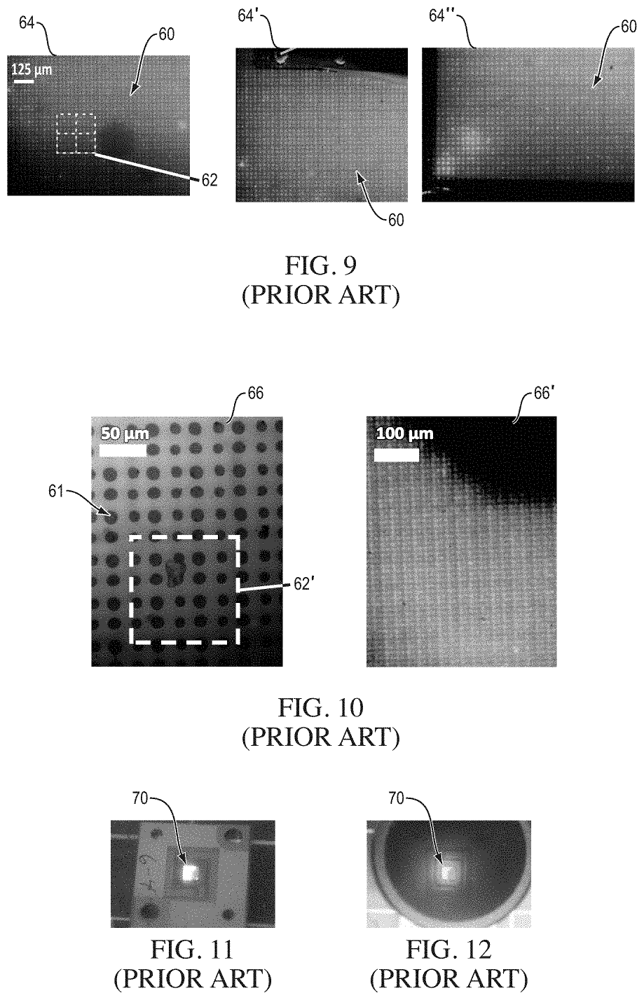

FIGS. 6-12 illustrate results of one of the “print and transfer” methods of FIG. 5, although the images accurately reflect typical results using either method. More particularly, and as discussed in detail below, FIGS. 6-8 illustrate QD arrays printed directly on the glass slide 24, 24′ prior to transferring the array to the LED chip 32, 32′. FIG. 9 illustrates an embodiment of a QD array printed in accordance with the method shown in Box A of FIG. 5. FIGS. 10-12 illustrate a QD array printed in accordance with the method shown in Box B of FIG. 5.

FIG. 6 illustrates a printed QD array after the uncured part has been rinsed away, with a 30 by 30 uniform printing, pixel size of about 15 μm to about 20 μm, a pitch distance of about 10 μm, and a QD concentration of about 2.5 mg/mL as shown in picture 40. A zoomed in subsection of the array is shown in picture 42. The QD array of pictures 40, 42 can be seen under UV illumination in pictures 44 and 46, respectively. FIG. 7 illustrates alternative configurations of printed QD arrays with varying shapes, sizes, pitch distances, and dot arrangements. It will be appreciated that an arrangement of the QD array can be varied based, at least in part, on the pattern of projected UV light that can contact and cure a deposited ink composition. For example, a QD array can have a dot size of about 20 μm and a pitch distance of about 50 μm, as shown in picture 50, and in detail in picture 50′, and corresponding UV illumination pictures 50″ and 50′″. A QD array can be printed as parallel lines with a thickness of about 25 μm and a pitch distance of about 50 μm as shown in picture 52, and in detail in picture 52′, and corresponding UV illumination pictures 52″ and 52′″. In yet another embodiment, a QD array can include closely packed 2-dot arrays with a dot size of about 25 μm and a pitch distance of about 25 μm, as shown in picture 54, and in detail in 54′, and corresponding UV illumination pictures 54″ and 54′″. FIG. 8 shows an exemplary cross-section profile 56 of a layer thickness of a cured pixel in a QD array formed by drop casting. These figures, when viewed in comparison with those of FIGS. 9-12, help to show the flexibility of configurations that are possible in view of the present disclosures with respect to pixel arrays, in addition to the flexibility of single pixel shape, which can be important for display performance.

FIGS. 9 and 10 illustrate photoluminescence test results of a QD array printed in accordance with the method shown in Box A and Box B, respectively, of FIG. 5. More particularly, picture 62 of FIG. 9 shows a QD array 60, with a 2-by-2 micro LED section denoted by square 62, after the first template transfer method shown in Box A of FIG. 5. Image 64′ shows an upper left corner of the array 60 and image 64″ shows a lower left corner of the array 60. FIG. 10 shows a QD array 61 after the second template transfer method of Box B of FIG. 5. Picture 66 shows a detailed view of the array 61 with a micro LED pixel 62′. The array 61 can have a pixel size of about 15 μm and a pitch distance of about 10 μm. Picture 66′ shows the photoluminescence of the array 61 after the second template transfer method. Notably, there is no effective improvement on the contrast. FIG. 11 shows a micro LED with QD dots 70 and FIG. 12 shows the micro LED with QD dots 70 through a 630 nm filter.

### Exemplary Printing Systems and Projection-Based Methods

As mentioned above, projection-based printing methods and ink compositions of the present disclosure can provide for printing of a wavelength converted directly onto a functional device (e.g., an LED), which is superior to the printing and transfer method, discussed with respect to FIGS. 6-12. This is because, at least in part: (1) the projection method and aperture developed in conjunction with the present disclosure can allow pattern projection and alignment simultaneously, thus offering higher pattern accuracy compared to transfer methods; and (2) the patterning uniformity can be determined by the projection uniformity and can be higher than that of transfer printing methods. Further, the direct printing provided for herein can be utilized on pixelated and non-pixelated LEDs. For example, the present techniques can allow for the formation of different color pixel-size converters in high-resolution and quality (e.g., in a sequential manner) while maintaining the intended shape and position (i.e., avoiding smearing due to wetting or de-wetting). In some non-limiting examples afforded by the present disclosures, direct printing can occur on photoluminescent materials in a layer-by-layer fashion and/or printing of photoluminescent materials of different colors in a layer-by-layer manner can occur without any physical masks.

The pixelated LED onto which the ink composition is deposited can have its surface treated to create a number of different configurations. These configurations can be well-defined shapes. By way of non-limiting example, square-shaped pixels can be formed by treating the surface on the pixelated LED in conjunction with modifying the printing system, such as by modifying an external lens attachment of a standard micro-stereolithography tool. The surface of the pixelated LED can be treated using plasma activation, chemical etching (e.g., wet chemical etching), or laser etching or ablation, among other techniques. In some instances, the LED surface can be covered with ultra-thin, transparent material having good thermal conductivity. A long-range topography can enable better selective physical confinement of the viscose ink composition, while shorter-range topography can enable better uniformity and adhesion of the ink composition.

The present disclosure can also allow for formulated LEDs to be thin while avoiding cross-talk among neighboring pixels. More particularly, in view of the present disclosure, the appropriate dose of UV light can be provided such that a thin film of the deposited ink composition (e.g., approximately in the range of about 1 μm to about 10 μm) can be cured by the UV light without creating optical cross-talk among neighboring pixels. Droplet-based methods, such as inkjet printing, which can be compatible with many colloids and polymer inks, often have difficulty with controlling a thickness that is about 10 μm or less, due, at least in part, to the aggregation of colloids after the evaporation of solvent inks. The present disclosure allows for wavelength converter pixel sizes that are approximately 25 μm or less, often approximately 10 μm or less, and still further approximately in the range of about 2 μm to about 5 μm, to be directly deposited onto a targeted, pixelated LED substrate. In fact, another benefit afforded by the present disclosure is the ability to utilize a direct printing method for a direct emissive microdisplay application utilizing III-V micro-LEDs. Prior to the present disclosure, transfer printing techniques were more common for such printing.

In addition to being able to print on a particularly thin-scale, sometimes referred to herein as ultra-thin (e.g., approximately 10 μm or less), the present disclosure also allows for high-throughput printing. More particularly, the methods disclosed are suitable for high throughput pixel printing of nanophosphor materials mixed in a transparent photopolymer in the visible region on a large substrate having dimensions approximately in the range of about 10 cm² by about 10 cm². It also allows for reproducible features sizes that are not readily achievable by other techniques known to those skilled in the art. For example, the reproducibility of high resolution transfer printing is low, due at least in part to the fact that the patterning process can rely on the uniformity of force applied to transfer the patterns on the stamp to targeted areas. Meanwhile, the fluidity and viscosity of inks used for ink jet or electrochemical jet printing can cause irregular and non-reproduceable pixel shapes.

While more details are provided below about various ink formulations or compositions, in some instances the formulations can contain a high concentration of nanophosphors (e.g., QDs), such as approximately in the range of about 25 mg/ML to about 50 mg/ML. The ink compositions provided for herein are formulated such that they do not generally undergo phase separation during a photopolymerization process despite the high concentration of nanophosphors. This is due, at least in part, to the thiol-ene chemistry in which cross-linked polymer networks are quickly formed to suppress aggregation of nanophosphors. In instances in which the surface of nanophosphors are caped with ligand, they can be less likely to participate in thiol-ene chemistry during photopolymerization and can enable higher loading up to the level of about 100 mg/mL in the ink composition e.g., QD+Chloroform+NOA61 formulation). As provided for herein, the ink formulation typically undergoes polymerization process by being exposed to UV/blue-Visible light. Other techniques for creating polymerization are possible (e.g., heating), although there may be challenges in adopting at least some such techniques for high resolution patterning.

Typically, organic materials are deposited during an additive manufacturing process through solution processing or vacuum techniques. Nanophosphors like QDs can be deposited using liquid-based processing. In the present disclosure, to the extent references are made to QD, a person skilled in the art will recognize other nanophosphors may also be suitable.

The ink compositions provided for in the present disclosure allow for a full conversion of blue radiation into green and/or red photons. More particularly, a QD concentration in the photo resin is increased. As described in greater detail below, in one exemplary embodiment, a chemistry of QD/PR48 is changed by adding Chloroform and/or mixing QD in NOA61 photoresin and Chloroform. In fact, a combination of QD+NOA61+Chloroform can enable 50 mg/ML of QDs in the ink formulation, as compared to that of 25 mg/mL of QDs in QD+Chloroform+PR 48 ink formulation. If higher concentration of QD beyond 50 mg/ML is desired for full conversion, then other techniques can be used, such as using Butylamine coated QDs, which have shorter ligands. Ink compositions of the present disclosure, which are photocurable, are also referred to herein as a “QD ink.”

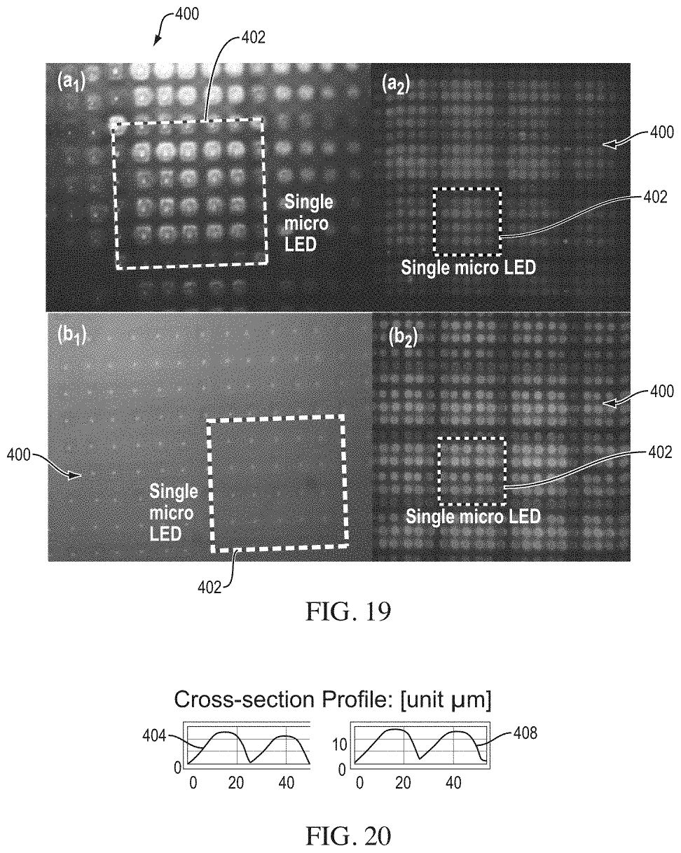

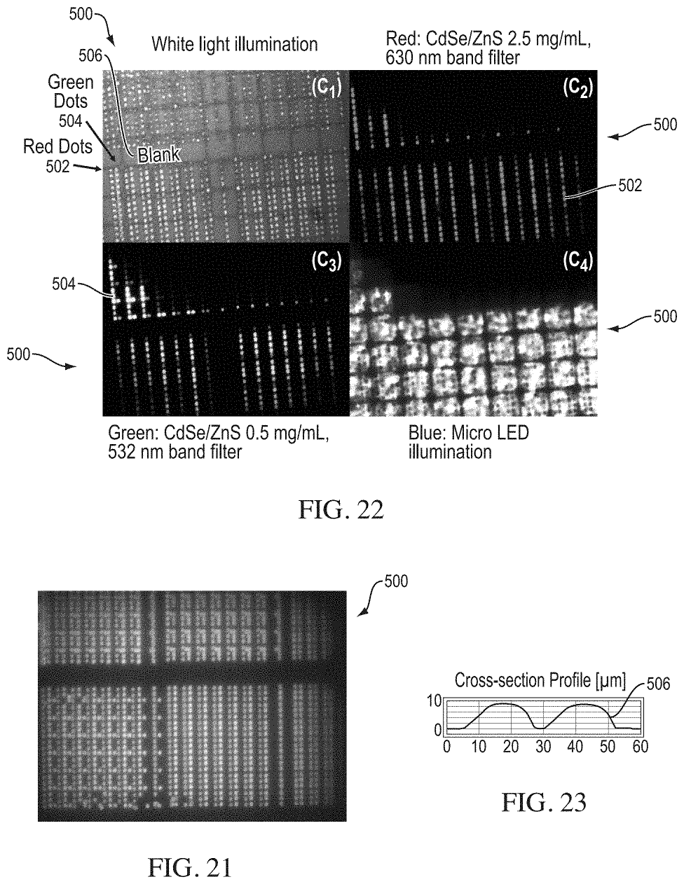

The disclosed ink compositions can also allow for higher absorption of blue radiation, including up to full conversion, due to the addition of non-absorbing scattering nanoparticles in the ink formulation. As described in detail below, an illustration of full conversion is provided, for example, in FIGS. 21 and 19, in which pixelated red 502 and green 504 color (the red being the dark shaded pixels in FIG. 22) converters array with pixel size of approximately 25 μm and pitch size, i.e., a periodicity of the pixel array, of approximately 30 μm. A gap or space between two adjacent pixels can be about 5 μm. The projection method provided for in the present disclosure can allow multi-material patterning for red, green, and blue full-color conversion. Meanwhile, the capability of high-resolution patterning can be seen in FIG. 0.19, in which about 25 micro-sized pixelated color converters cover a single blue micro LED pixel having a size of about 100 μm.

### Projection Based μ-Stereolithography Apparatus

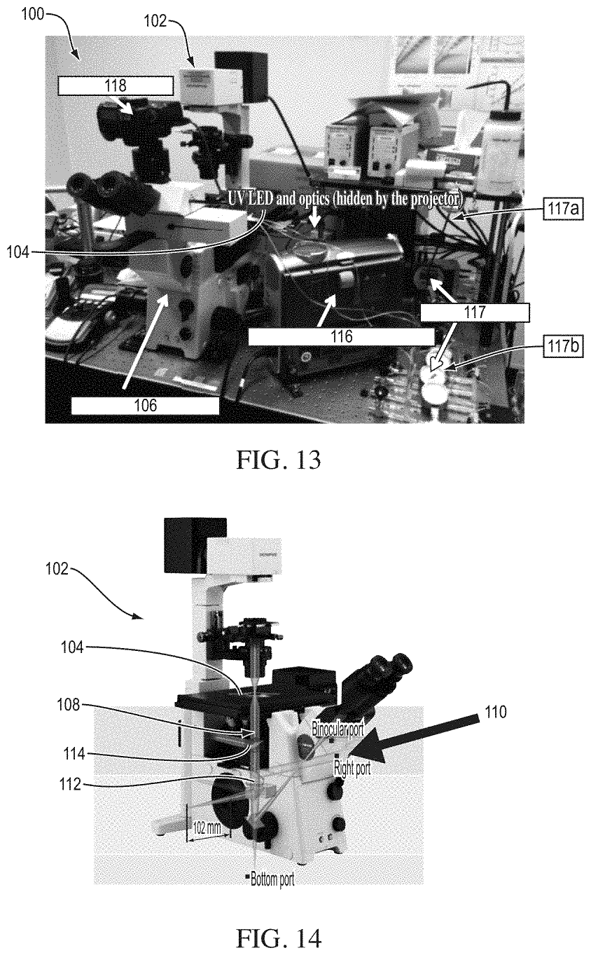

FIGS. 13 and 14 show one embodiment of an additive manufacturing system 100 that can be used to achieve direct printing of a wavelength converter on a micro LED, or other functional substrate, with an improved resolution and pattern alignment as compared to prior techniques. The system 100 can include a stereolithography apparatus 102 with a dispenser 117 that can deposit a photocurable nanophosphor ink composition onto at least one of a substrate (e.g., an LED) placed on a stage 104 and a cured photocurable nanophosphor ink composition layer that can be received, e.g., previously cured, on the substrate. In some embodiments, the dispenser 117 can include tubing 117a and a pressure control 117b, together which can draw the ink composition from a reservoir (not shown) or other location where an ink can be disposed, pass the ink composition through the tubing, and deposit the ink composition onto at least one of the substrate placed on the stage and the cured photocurable nanophosphor ink composition later that can be received on the substrate. One skilled in the art will appreciate that other embodiments of a dispenser for supplying ink in conjunction with the system 100 fall within the scope of the present disclosure. The apparatus 102 can also include an inverted optical microscope 106, which can have an optical path 108 (see FIG. 14) that can direct light that enters the apparatus through an entry port 110 to project onto the stage 104. It will be appreciated that at least a portion of the stage 104 can be made of a transparent material, such as glass, which can allow for light to be projected therethrough. Accordingly, the light (e.g., a UV light) can cure portions of the photocurable ink deposited on the substrate and/or the previously cured nanophosphor ink composition layer that are exposed to the projected light pattern. In some embodiments, the optical path 108 can include one or more lenses 112 and/or mirrors 114, which can direct the light to the stage 104. The additive manufacturing system 100 can further include a projector 116 that can project light from a light source (e.g., a UV light source, not visible) into the entry port 110 of the apparatus 102. In some embodiments, the system 100 can also include a camera 118, such as a DSLR CCD camera.

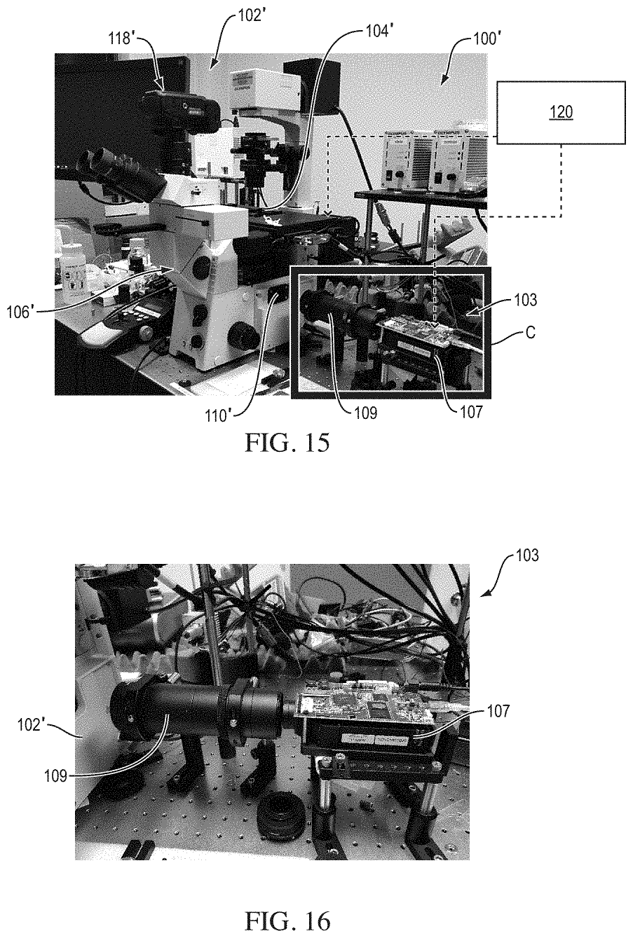

FIGS. 15 and 16 show another embodiment of an additive manufacturing printing system 100′ of the present disclosure, which can include a projection based micro-stereolithography apparatus 102′ with a modified inverted microscope set-up, as described in detail below. The printing system 100′ can print a wavelength converter directly on a functional device, e.g., a micro LED, such that a need for a template transfer procedure can be eliminated. The micro-stereolithography apparatus 102′ can be similar to the apparatus 102 of FIGS. 13 and 14, except as described herein and as would be understood by one skilled in the art. More particularly, the micro-stereolithography apparatus 102′ can have a stage 104′, an inverted microscope 106′, and a dispenser 117 (FIG. 13). Further, the apparatus 102′ can include a modified inverted microscope setup 103, which can, among other things, improve pattern alignment of a projected light pattern during multiple exposure.

The modified inverted microscope setup 103 can include a UV DLP projector 107 and a collimator 109, as shown in box C of FIG. 15 and in greater detail in FIG. 16. The projector 107 can project light, such as UV light, from a light source through the collimator 109 and into an entry port 110′ of the apparatus 102′. The UV light can be directed from the entry port 110′ by an optical path, such as the optical path 108 shown in FIG. 14, to be projected onto the stage 105′. More particularly, the UV light can be projected through a transparent portion of the stage 104′ and onto a functional substrate placed on the stage, a photocurable nanophosphor ink deposited onto the substrate, and/or photocurable nanophosphor ink deposited onto a cured photocurable nanophosphor ink composition received on the substrate. In this manner, the projected UV light can cure the deposited nanophosphor ink onto the substrate and/or the previously cured layer of photocurable nanophosphor ink on the substrate where the deposited ink is exposed to the UV light. The projected UV light can be projected in a particular pattern based, at least in part, on a desired configuration of the wavelength converter.

By way of non-limiting example, the UV DLP projector 107 can have a digital micro-mirror device (DMD) with a 912×1140 resolution from the projector. The UV light projected by the projector 107 can be used to cure photoresin, i.e., the photocurable nanophosphor ink composition, instead of a series of physical photomasks. In some embodiments, the stage 104′ can be an automatic x-y stage with about 1 micrometer (μm) positioning resolution on the microscope. By way of non-limiting example, in some embodiments, the UV DLP projector 107 can be a Wintech Pro 4500 UV DMD projector, TI WXGA (912×1140) DMD with a contrast ratio of 1000:1.

In one exemplary embodiment, 405 nm UV light of the patterned light can be projected from the high-power UV DLP projector 107 and can be passed through the optics 108 of the stereolithography apparatus 102′ to be projected on to the QD ink for curing on the surface of a pixelated LED or on a previously cured layer of QD ink. As noted above, the pixelated LED can be located on the automatic x-y stage 104′ with about 1 μm positioning resolution on the microscope. The inverted microscope 106′ can be applied to achieve projection resolution down to about 10 μm, which can facilitate the pattern alignment of the UV light on the pixelated micro-LED. The dose of UV exposure to cure the QD ink can be controlled by adjusting a projection time and/or power of the projector 107. Uncured QD ink, i.e., QD ink deposited onto the LED or onto a previously deposited layer of QD ink that was not exposed to the projected UV light, can be washed away, and the x-y automatic stage 104 can be operated to move the LED substrate to the next printing position(s) of a different QD composition.

More generally, the additive manufacturing printing system 100 can include a dispenser 117 that can deposit the QD ink composition, a projector, e.g., the UV DLP projector 107, that can project a pattern onto a substrate, previously deposited ink composition, and/or the deposited ink composition, and a light source(s) (not visible) that can cure at least a portion of the deposited ink. The system 100 can also include a controller 120 that can control, operate, or otherwise provide commands to components like the dispenser, projector 107, and light source so that the various actions can be synced to efficiently produce the desired three-dimensional object (e.g., an LED). The printing system 100 can include a stage, such as the stage 105′ discussed above, and the controller can also control, operate, or otherwise provide commands to the stage.

### Description of the Ink for Stereo-Lithography for Micro-Leds

In general terms, an ink composition for stereo-lithography as provided for herein can include at least one photo-curable polymer of proper rheological properties and light converting sub-micron particles dispersible in such polymer. Physical and chemical characteristics of the ink composition and characteristics of a surface receiving the ink can typically enable wetting of the surface by the ink, photo-activation of the crosslinking process, and formation of the uniform solid nanophosphor (e.g., QD) composite films. By way of non-limiting example, the ink composition can be a nanophosphor ink, which may contain a variety of photo-curable resins, such as one or more of the photo-curable resins described herein. By way of non-limiting example, transparent photo-curable resins are absorbing in UV and sometimes also at short blue range of the visible spectrum (VIS). Transparent photo-curable resins can be epoxy-, urethane- or acrylate-based polymer compositions, but can also come from the groups of photo-curable silicones, polysiloxanes, or their hybrid formulations. In some embodiments, properties of these polymer compositions can be tailored toward specific functionalities by use of a base monomer and various additives, which can enable crosslinking processes, modify rheological properties, and/or affect adhesion. Examples of such modifications can be shown using the example of the family of the commercial epoxy-type SU-8 resist. Table 3 below shows a range of compositions of the SU-8 resin of various viscosities, which may be employed for optimization of the processes and resultant films.

TABLE 3
SU-8 Photoresist - selected examples
of properties and process conditions.

| Product Name | Viscosity (cSt) | Thickness (μm) | Spin Speed (rpm) |
|---|---|---|---|
| | | 1.5 | 3000 |
| SU-8 2 | 45 | 2 | 2000 |
| | | 5 | 1000 |
| | | 5 | 3000 |
| SU-8 5 | 290 | 7 | 2000 |
| | | 15 | 1000 |
| | | 10 | 3000 |
| SU-8 10 | 1050 | 15 | 2000 |
| | | 30 | 1000 |
| | | 15 | 3000 |
| SU-8 25 | 2500 | 25 | 2000 |
| | | 40 | 1000 |

Furthermore, a polymer for the photo-curable composition, i.e., the ink composition, can be selected, for example, from the transparent resins from Norland Optical. Examples of optical photo-curable adhesives from this manufacturer are shown in Table 4. Selection of a photo-curable adhesive can be made, at least in part, based on one or more of a desired index of refraction, an application-related adhesion, desired range of hardness, and/or recommended temperature range in final application.

TABLE 4
Examples of Norland Optical resins.

| | Urethane based | | Refractive | | | | |
|---|---|---|---|---|---|---|---|
| | formulation with | Viscosity | index of | Temp. | | Curing | |
| | some specific | at 25 C. | cured | range | Hardness | wavelength, | Adhesion to |
| Product | components | (cPs) | polymer | (° C.) | shore D | dose | materials |
| NOA 61 | Mercapto-ester, | 300-450 | 1.56 | 125 | 85 | 365 nm, | glass, metals, |
| | triallyl Isocyanuate | | | | | 3 J/cm² | fiberglass, |
| | | | | | | | glass-filled |
| | | | | | | | plastics |
| NOA76 | Aliphatic Urethane | 3500-5500 | 1.51 | 125 | 60 | 315-400 nm, | glass to |
| | Acrylate, | | | | | 5 J/cm² | plastic |
| | Tetrahdrofurfuryl | | | | | | |
| | Methacrylate, | | | | | | |
| | acrylate Acid Ester | | | | | | |
| | 2(2-thoxyehoxy) | | | | | | |
| NOA139 | Aliphatic Urethane | 865 | 1.39 | 90 | 45 | 315-450 nm, | glass to |
| | Acrylate, Acrylate | | | | | 6 J/cm² | glass |
| | Monomer | | | | | | |
| NOA148 | Aliphatic Urethane | 1500-2000 | 1.48 | 90 | 90 | 315-395 nm, | glass to |
| | Acrylate, Fluoroester, | | | | | 6 J/cm² | glass |
| | Isobornyl Acrylate, | | | | | | |
| | 1.6 Hexanediol | | | | | | |
| | Diacrylate | | | | | | |

For example, materials can be selected such that the ink composition can have an index of refraction approximately greater than about 1.35, and more particularly, in some embodiments, the index of refraction can be approximately in the range of about 1.35 to about 2.2. By way of non-limiting examples, the refractive index for SU8 is approximately in the range of about 1.5 to about 1.6, for PMMA is approximately in the range of about 1.48 to about 1.5, and for thiol-ene (NOA) polymer is approximately in the range of about 1.39 to about 1.6.

As various additives can be used for achieving one or more desired functional properties, the chemical characteristics of the additive(s) may exhibit enhanced reactivity toward quantum dots chemistry, and thus, need to be properly selected and used with caution. As one of the examples of such selection, the hybrid acrylate resin can be used as a host for the QDs in conversion application. Acrylate resins and hybrid-acrylate resins can accommodate well the typical colloidal QDs without substantially degrading their properties. Characteristics of this kind of polymers from Microresist Technologies, GmbH are shown in Table 5.

TABLE 5
Examples of hybrid polymers of various viscosity from Macroresist Technologies, GmbH.

| | | | | | | | | |
|---|---|---|---|---|---|---|---|---|
| Material | Ormo- | Ink- | Ormo- | Ormo- | Ormo- | Ormo- | Ormo- | Ormo- |
| specification | Comp | Ormo | Clear | clear30 | Clear FX | Stamp | Core | Clad |

Liquid material before patterning process

| | | | | | | | | |
|---|---|---|---|---|---|---|---|---|
| Solvent-free | yes | no | yes | yes | yes | yes | yes | yes |
| Viscosity (Pa · s) | 2.0 +/− 0.5 | | 2.9 +/− 0.3 | 30 +/− 3 | 1.5 +/− 0.3 | 0.4 +/− 0.2 | 2.9 +/− 0.4 | 2.5 +/− 1.0 |
| Film thickness upon | 20 | | 30 | 100 | 20 | 10 | 30 | 30 |
| spin coating (μm) | 10-60 | | 20-95 | 50-270 | 10-60 | 5-35 | 20-90 | 20-90 |
| 3000 rpm | | | | | | | | |
| 6000-1000 rpm | | | | | | | | |

| | | | | |
|---|---|---|---|---|
| Spectral sensitivity | 300-400 | 300-410 | 300-410 | 300-390 |
| photo-curing (nm) | | | | |

Such basic composition is sufficient for demonstrating the capabilities of the stereolithographic printing tool for general usage. However, it is not sufficient for crafting full conversion optical films for pixelated LEDs. This is, at least in part, because of the limited loading of the QDs into the composition (QDs+organic matter/ligands with chemical reactivity). Even the films with the maximum loading of the QDs (still allowing curing of the composition) are not typically thick enough to absorb all the blue light emitted by the LED. The desired film thickness can easily become impractical, especially in small- (i.e., micron-) range geometries (approximately less than about 50 μm), as these typically utilized for pixelated LEDs.

The ink compositions of the present disclosure can incorporate non-absorbing, scattering nanoparticles. Inclusion of such nanoparticles within the ink composition can cause a scattering of blue light within the ink film, which can increase the utilization of the blue light and greater absorption and down-conversion of the latter. By way of non-limiting example, the scattering nanoparticles can be selected from the groups of transparent oxides (e.g., titanium dioxideTiO₂, zirconium dioxide ZrO₂, silicon dioxide SiO₂) or alumina, undoped YAG, barium sulfateBaSO₄ (all three of which can also be considered to be transparent oxides). In some instances, utilizing materials with greater thermal conductivity can improve performance of the QDs on the LED chip. This is further elaborated upon in U.S. Patent Application Publication No. 2016/0369954 of Anc et al., which is incorporated by reference herein in its entirety.

In some embodiments, the surface of an LED, or other functional substrate, receiving the deposition of the QD ink can be made of material(s) that result in good thermal conductivity (e.g., aluminum oxide Al₂O₃). A thermally conductive material can enable better heat conduction between the converter and the LED chip mounted on a heat sink.

In some embodiments, the surface of the substrate, e.g., the LED, can include one or more specific topographic features that can provide additional functionality and improvement. Fabrication of the specific topographic feature(s) can be included as part of the LED process flow. The one or more specific topographic features can include, for example, ordered long-range geometry that can define external borders of an area receiving one color of the ink. Other topographic features can be ordered and/or randomized in a smaller scale (e.g., within the defined borders for the area of deposition of one ink), and their function can enable uniformity of the film and adhesion to the receiving surface.

In some embodiments, after deposition of all ink(s) on the pixelated LED, the entire surface may be coated with a transparent or hazing film, which can provide benefits such as environmental protection and light extraction.

### Colloidal Qds as a Component of the Qd Ink

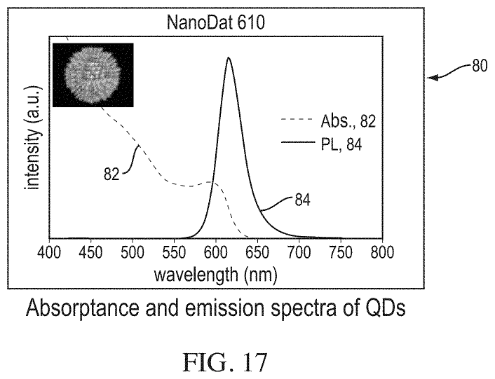

Narrow-band emitters can offer benefits of color quality and conversion efficiency in backlighting and SSL applications. Luminescent colloidal QDs are among materials suitable for such applications and can offer not only specific optical properties, but also potential for cost-efficient manufacturing. Certain optical properties of a luminescent colloidal QD are illustrated in FIG. 17. More particularly, a graph 80 shows an absorptance spectra 82 and a photoluminescence spectra 84 of a colloidal QD across a wavelength (nm).

QDs can be narrow-band emitters with broad absorption spectrum in a wavelength range from approximately UV up to their first excitonic peak. They can be non-scattering and efficient. Contemporary colloidal QDs can exhibit efficiency in dispersions in non-polar solvents (routinely approximately in the range of greater than about 80% to about 90% in large volumes) and optimized polymer composites (routinely approximately in the range of about 70% to about 80%). Their peak emission wavelength can be tuned within a few nanometers. In colloidal dispersions, the QDs can be overcoated with organic ligands, passivating the surface, preventing agglomeration, and enabling miscibility with host materials. The nature of these ligands can affect the feasibility of formulating the QD composites and their performance in respective applications. At present, the QD/polymer composites can be employed in back lighting and SSL applications as the remote color correcting films.

In many cases, the optical components with QDs can be fabricated as free-standing parts with the application-specific form factor. They may comprise one or more compositions of the QDs with polymers. Hybrid organic/inorganic substances may also form dense assemblies on the supporting substrate. To prevent degradation of the QD properties in an ambient environment, these components may be encapsulated.

Selective deposition of QDs can be challenging, especially when the QD ink is to be confined to a small area with well-defined edges and uniform coverage. Positioning of various wavelength emitting QDs in closed vicinity can be an additional difficulty. These issues can at least be addressed in the sections describing the ink compositions and the receiving surface of the LED in accordance with the present disclosure.

### Test Results of Methods, Systems, and Compositions of the Present Disclosure

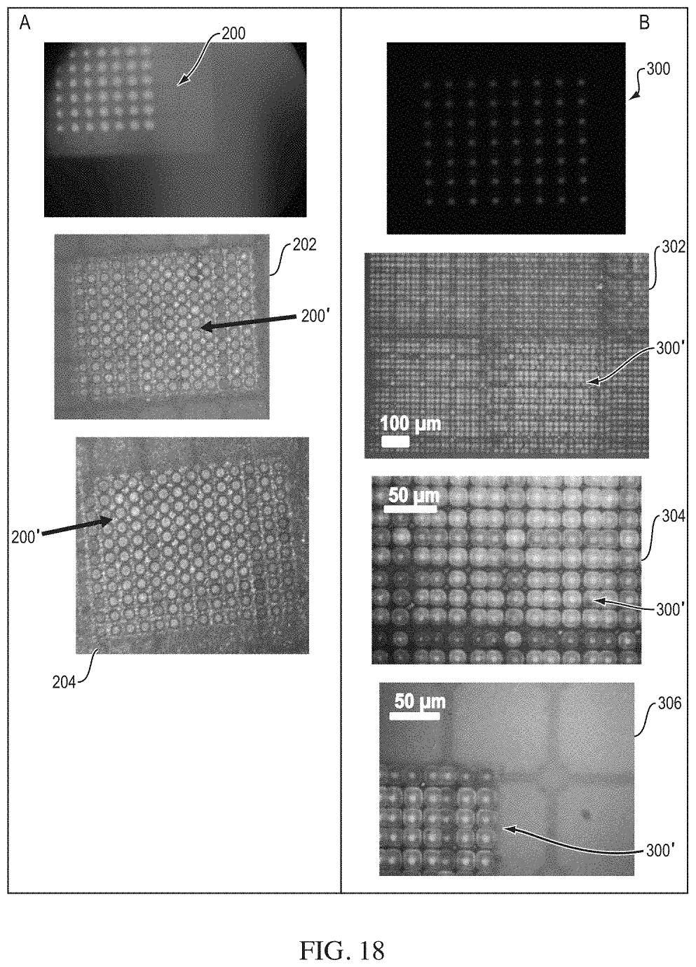

FIGS. 18-25 illustrate results of direct printing of ink compositions of the present disclosure onto an LED substrate with printing methods as described herein. FIG. 18 shows images in box A taken in conjunction with the printer system 100 of FIG. 13 and images in box B taken in conjunction with the printer system 100′ of FIGS. 15 and 16. More particularly, box A of FIG. 18 shows a projected light pattern 200 that can be projected onto the glass slide 104 of the printer system 100 of FIG. 13. The projected light pattern 200 can cure photocurable QD ink in areas where the ink is exposed to the light pattern through the glass slide 104. Images 202, 204 show a QD array 200′ that can be formed, at least in part, from exposure of photocurable QD ink to the projected light pattern 200. The images 202, 204 of the QD array 200′ show that, at least in some instances, there can be high contrast at inter space between the projected pattern and background illumination, which can be beneficial for reducing light leakage from patterned QD pixels. Box B of FIG. 18 shows a projected light pattern 300 that can be projected onto the glass slide 104′ of the system 100′, as described above with respect to FIGS. 15 and 16. Images 302, 304, and 306 each show at least a portion of a QD array 300′ that can be formed, at least in part, from exposure of photocurable QD ink to the projected light pattern 300. As can be seen from the images 302, 304, 306, the system 100′ can provide for improved pattern alignment of the projected pattern 300. This can be beneficial over multiple exposures of the pattern 300 to photocurable QD ink to form the QD array 300′ on a micro LED or other functional substrate.

FIG. 18 shows one embodiment of an RGB full-color conversion printed on a micro-LED in accordance with the present disclosure. More particularly, FIG. 19 includes four photoluminescence photos (a₁), (a₂), (b₁), (b₂) of a portion of a micro LED chip 400 that can include a plurality of single micro-LEDs, such as a single micro-LED 402. The single micro-LED 402 can have about 25 pixels, in a 5-by-5 pixel arrangement, with a pixel size of about 25 μm and a pitch distance of less than about 5 μm. The photoluminescence photos (a₁), (a₂), (b₁), (b₂) of FIG. 19 were taken with 630 nm and 532 nm band filters. An RGB full-color conversion wavelength converter can be printed on directly on the single micro-LED 402. A multiple exposure process can be used to print an RGB full-color conversion wavelength converter onto one or more of the single micro-LEDs that make up the micro LED chip 400. A down conversion from blue light (a₁) to red light (a₂) and green light (b₂) can have improved photoluminescence contrast, for example CdSe/ZnS QD for red with a concentration of 2.5 mg/mL and CdSeS/ZnS QD for green with a concentration of 0.5 mg/mL. FIG. 20 show examples of a cross-section profile of two pixels 404, 408 of the micro-LED 402 that can each have a trapezoid cross-section and can range in height from about 10 μm to about 15 μm.

FIG. 20 shows a micro-LED chip 500 with RGB full-color conversion (i.e., full-color wavelength converters of the present disclosure) printed thereon. By way of non-limiting example, and as can be seen in greater detail in the photoluminescence photos (C₁), (C₂), (C₃), (C₄) of FIG. 22, a full-color wavelength converter of the present disclosure, such as that printed on the micro-LED 500, can, in at least some embodiments, include a column of red QDs 502 adjacent to a column of green QDs 504. The red QDs can have this pattern repeated one or more times across the micro-LED 500. The micro-LED 500 can also have a background 506, or blank space, that can be free from cured QD ink. Photo (C₁) shows the micro-LED 500 with white light illumination; photo (C₂) shows the micro-LED 500 with illuminated red QDs 502, CDSe/ZnS 2.5 mg/mL, 630 nm band filter; photo (C₃) shows the micro-LED 500 with illuminated green QDs 504, CdSeS/ZnS, 0.5 mg/mL, 532 band filter; and photo (C₄) shows the micro-LED 500 with blue illumination. The micro-LED 500 with the full-color wavelength converter, as shown in FIGS. 21 and 22, can have an improved patterning contrast between QDs 502, 504 and the background 506. FIG. 23 shows an example of a cross-section profile 506 of a pixel of the micro-LED 500. The pixel can have a height ranging from about 10 μm to about 15 μm with a trapezoid cross-section.

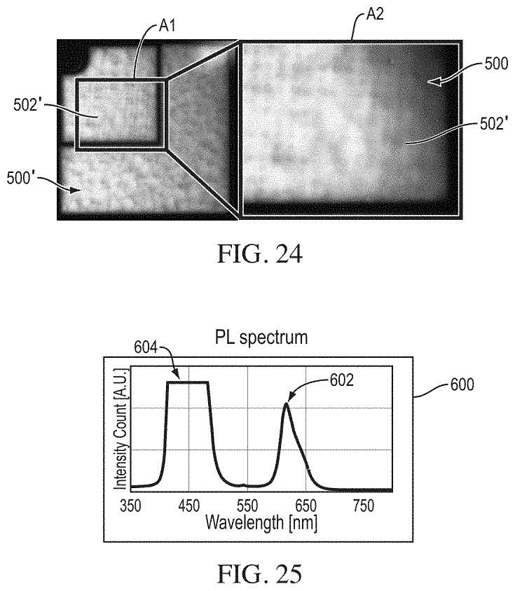

In some embodiments, the down conversion efficiency can be improved by increasing the QDs concentration. For example, FIG. 24 shows a micro-LED 500′ that can have a red QD 502′ concentration of about 25 mg/mL, which can represent about a 10 time increase over that of the red QD 502 concentration in the micro-LED 500. The box A2 shows a closer view of a portion A1 of the micro-LED 500′. FIG. 25 shows a photoluminescence spectrum 600 of a red QD 502, 502′. A peak intensity 602 can occur at a wavelength of about 620 nm. A saturation of a photo-detector used to measure the spectrum intensity can occur over an emission wavelength 604 of a blue LED. The emission wavelength 604 of the blue LED can be centered around about 450 nm.

The present disclosure provides for a number of exemplary embodiments. Some non-limiting examples include the following, which can standalone as embodiments and/or be combined with other embodiments provided for herein or otherwise derivable from the present disclosure in view of the knowledge of one skilled in the art.

In some embodiments, InGaN blue LEDs can be produced by subdividing larger emitting surface area (e.g., about 4 sq. mm) into multiple micro-emitting surfaces (e.g., about 115×about 115 μm²).

In some embodiments, a top surface of the micro-emitting surfaces can be further divided and processed to obtain optimum surface energy and desired pixel shape during printing process.

In some embodiments, each pixel surface can be etched via chemicals or laser irradiation, among other techniques.

In some embodiments, pixelated LEDs can be coated with transparent oxides such as TiO₂, ZrO₂, SiO₂, Al₂O₃, YAG, BaSO₄, etc.

In some embodiments, QDs can be mixed in toluene (e.g., about 25 mg/mL) and then mixed with PR 48 photo resin to approximately 2.5 mg/mL. A mixed suspension can be used, for example, to print on substrates, e.g., glass, sapphire, LEDs, pixelated LEDs, etc.

In some embodiments, QDs can be mixed in toluene (e.g., about 25 mg/mL), and then mixed with a similar volume of PR 48 photo resin. The mixture can then be degassed of Toluene for example, under a vacuum to obtain a QD concentration in PR 48 of about 25 mg/mL. In some such embodiments, a droplet coat (about 5 μL) of photo resin/QDs composite can be deposited on an OSRAM micro LED chip. A kim wipe(s) can be used to clean redundant liquid at the edge of the chip to get a near flat top interface between liquid and air. The micro LED chip can be put on to the inverted microscope stage of the lab set-up described above, with the focus on to the top surface of the chip. The automatic x-y stage can be used to align a printing area to the micro-LED array. A pattern can be projected onto the chip with a controlled exposure dose. The automatic x-y stage can be operated to move the micro LED chip to a next printing position. The actions of projecting the pattern and operating the x-y stage can be repeated until the whole printing area is converted. Uncured photoresin can be removed with an IPA rinse and the remaining portions can be dried, such as by air-drying. These steps can be further repeated to produced additional layers, resulting in multilayer coatings.

In some embodiments, Toluene can be replaced by Chloroform as the inter-step solvent enables higher concentration of QD (up to approximately 50 mg/mL) into NOA 61 without aggregation of the QDs.

In some embodiments, QD converters can be mixed in photocurable polymers such as, by way of non-limiting examples: (i) SU-8 photoresist; (ii) Poly(ethylene glycol) diacrylate (PEGDA); (iii) 1,6-Hexanediol diacrylate (HDDA); (iv) PR-48 [di(trimethylolpropane) tetraacrylate (DTPTA), trimethylolpropane ethoxylate triacrylate (TPET), 2-[[(butylamino)carbonyl]oxy]ethylacrylate (BACA), and 2,5-bis(5-tert-butyl-benzoxazol-2-yl)thiophene (TBT) and ethyl (2,4,6-trimethylbenzoyl) phenylphosphinate (TPO)]; and/or (v) NOA 61 (which includes tetrafunctional thiol in a near 1:1 molar ratio with a trifunctional alkene, as well as a photoinitiator).

In some embodiments, QDs can be suspended in one or more of toluene, ethanol, hexane, chloroform, octane, or polyisobutylene and can be mixed (e.g., up to about 60 vol. %) in a UV curable ink that can include acrylic monomers (approximately in the range of about 25 vol. % to about 40 vol. %), as well as N-Vinyl caprolactam (approximately in the range of about 10 vol. % to about 25 vol. %), hexamethylene diacrylate (approximately in the range of about 10 vol. % to about 25 vol. %), and/or other acrylates for reaction.

In some embodiments, QDs can be mixed in a UV-curable ink composition that includes a diallyldiphenylsilane, methacryl polyhedral oligomeric silsesquioxanes, and 2,4-di-tertbutylphenol.

In some embodiments, QD ink can include COOH-functionalized CdSe/ZnS dispersed in tetradecane with particles concentration up to approximately 30 wt. %.

In some embodiments, a QD converter having one or more of the provided compositions can be printed using stereo-lithography with an Ember printer from Autodesk, Inc. of San Rafael, Calif. and micro-stereo-lithography with inverted microscopy equipped with a UV DMD digital light projector.

In some embodiments, adhesion of the QD ink to the surface LED can be enhanced by surface treatment techniques.

In some embodiments, scattering particles can be added in the QD ink formulation for efficient extraction.

In some embodiments, a printed pixel height can be approximately in the range of about 1 μm to about 15 μm after curing.

In some embodiments, an array of converter pixels (e.g., 5×5) on a single blue LED pixel of size approximately 115 μm×approximately 115 μm can be printed with varying sizes approximately in the range of about 5 μm to about 25 μm, and in some instances as low as about 2 μm.

In some embodiments, QD converters can include CdSe/ZnS, CdSeS/ZnS, etc.

In some embodiments, a viscosity of the ink formulation can be varied from approximately 2 cps to approximately 500 cps.

The present disclosure enables systems, apparatuses, methods, and ink formulations supported by the written description. For example, the disclosure provides for a light converter for LEDs with RGB micro-pixels and an LED with such a converter. The converter can be deposited on the LED wafer by stereolithographic methods, for instance forming an array of pixels that can be activated selectively by the underlying LED.

By way of further example, the disclosure provides for a light converter containing a photo-curable ink composition(s) that includes at least one polymer, nanophosphors (e.g., QDs), and a light-scattering additive(s). In some embodiments, the photo-curable ink composition(s) can include a nanophosphor (e.g., QD) concentration above approximately 50% without any scattering additives. Examples of light-scattering additives that can be used include: transparent oxides (e.g., TiO₂, ZrO₂, SiO₂), alumina, undoped YAG, BaSO₄, etc.

Many different LED configurations are made possible by the present disclosure. For example, the disclosure provides for an LED with a micron-pixel design that includes the deposited composition absorbing at least 90% of light emitted by the LED micro-pixel.

By way of further example, the disclosure provides for an LED with a micro-pixel design that includes a layer stack comprising a transparent material(s) on its top surface, the layer stack being for receiving the deposition of the light converting films. In some embodiments, the top surface of the transparent material(s) can be sub-pixelated further, such as having sizes approximately 10 μm or less. In some such embodiments, the surface can be treated and/or structured using reactive plasma, chemical etching, and/or laser etching, among other treatment techniques provided for herein or otherwise known to those skilled in the art.

By way of still further example, the disclosure provides for an LED with a micro-pixel design that includes a layer stack comprising a transparent material(s) on its top surface, the layer stack being for receiving the deposition of the light converting films, and having a long-range topography that defines selective ink areas.

By way of yet another example, the disclosure provides for an LED with a micron-pixel design that includes a layer stack comprising a transparent material(s) on its top surface, the layer stack being for receiving the deposition of the light converting films, and having a short-range topography on the selective ink areas that enables uniformity of the film and/or adhesion.

The present disclosure also enables light converter pixels having sizes approximately 25 μm or less, approximately 10 μm or less, approximately 5 μm or less, and approximately 2 μm, such pixels being deposited on an LED with micro-pixel design, the pixels maintain a square shape.

Examples of the above-described embodiments can include the following:
1. A method of additively manufacturing an LED, comprising:
   depositing a photocurable nanophosphor ink composition onto at least one of a substrate or a cured photocurable nanophosphor ink composition;
   projecting a pattern onto at least one of the substrate, the cured photocurable nanophosphor ink composition, or the deposited photocurable nanophosphor ink composition; and
   curing at least a portion of the photocurable nanophosphor ink composition based on the projected pattern.
2. The method of claim 1, further comprising:
   depositing an additional photocurable nanophosphor ink composition onto at least one of the substrate or the cured photocurable nanophosphor ink composition;
   projecting a second pattern onto at least one of the substrate, the cured photocurable nanophosphor ink composition, or the deposited photocurable nanophosphor ink composition;
   curing at least a portion of the additional photocurable nanophosphor ink composition based on the projected second pattern; and
   continuing to deposit, project, and cure until a three-dimensional LED having nanophosphors disposed therein is produced, the depositing being done with one or more further photocurable nanophosphor ink compositions and the projecting being done with one or more further patterns.
3. The method of claim 2, wherein the three-dimensional LED is configured to fully convert blue light-emitting pixels to at least one of red light-emitting pixels or green light-emitting pixels.
4. The method of claim 2 or 3, wherein pixels of the three-dimensional LED have a light-emitting pixel size that is approximately 25 μm or less.
5. The method of claim 4, wherein the light-emitting pixel size is approximately 10 μm or less.
6. The method of claim 5, wherein the light-emitting pixel size is approximately in the range of about 2 μm to about 5 μm.
7. The method of any of claims 2 to 6, wherein a distance between light-emitting pixels of the three-dimensional LED is approximately 5 μm or less.
8. The method of any of claims 2 to 7, wherein the three-dimensional LED comprises a plurality of square light-emitting pixels.
9. The method of any of claims 2 to 8, wherein a thickness of the three-dimensional LED is approximately in the range of about 2 μm to about 10 μm.
10. The method of any of claims 2 to 9, further comprising washing away uncured photocurable nanophosphor ink composition prior to depositing the additional photocurable nanophosphor ink composition.
11. The method of any of claims 2 to 10, further comprising coating a surface of the three-dimensional LED with a film having transparent or hazing properties after depositing all additional photocurable nanophosphor ink compositions is completed.
12. The method of any of claims 1 to 11, further comprising treating a surface of the substrate by at least one of chemically etching the surface, laser etching the surface, laser ablating the surface, or plasma activating the surface.
13. The method of any of claims 1 to 12, wherein the substrate is a pixelated LED substrate.
14. An additive manufacturing printing system, comprising:
   a dispenser configured to deposit a photocurable nanophosphor ink composition onto at least one of a substrate or a cured photocurable nanophosphor ink composition;
   a projector configured to project a pattern onto at least one of the substrate, the cured photocurable nanophosphor ink composition, or the deposited photocurable nanophosphor ink composition;
   a light source configured to cure at least a portion of the photocurable nanophosphor ink composition based on the pattern projected by the projector; and
   a controller configured to selectively operate each of the dispenser, the projector, and the light source to produce a three-dimensional LED that includes the substrate and the cured photocurable nanophosphor ink composition.
15. The system of claim 14, wherein the controller is configured to control the light source by controlling at least one of an exposure time and a power of the light source.
16. The system of claim 14 or 15, further comprising:
   a stage on which the substrate is located,
   wherein the controller is further configured to operate movement of the stage to locate the substrate at a desired location for at least one of receiving the photocurable nanophosphor ink composition from the dispenser, receiving the projected pattern from the projector, or receiving light from the light source to cure the photocurable nanophosphor ink composition.
17. The system of any of claims 14 to 16, further comprising a pass-through optic configured to at least allow light from the light source to be passed therethrough, towards the substrate.
18. An LED, comprising:
   a pixelated LED having a plurality of individually addressable pixels configured to be controlled electrically for light emission; and
   a wavelength converter deposited onto the pixelated LED, the wavelength converter comprising a plurality of nanophosphors, and the wavelength converter being configured to fully convert blue light-emitting pixels of the pixelated LED to at least one of red light-emitting pixels or green light-emitting pixels.
19. The LED of claim 18, wherein light-emitting pixels of the pixelated LED have a size that is approximately 25 μm or less.
20. The LED of claim 19, wherein the light-emitting pixel size is approximately 10 μm or less.
21. The LED of claim 20, wherein the light-emitting pixel size is approximately in the range of about 2 μm to about 5 μm.
22. The LED of any of claims 18 to 21, wherein a distance between light-emitting pixels of the pixelated LED is approximately 5 μm or less.
23. The LED of any of claims 18 to 22, wherein the pixelated LED comprises a plurality of square light-emitting pixels.
24. The LED of any of claims 18 to 23, wherein a thickness of the pixelated LED in combination with the wavelength converter is approximately in the range of about 2 μm to about 10 μm.
25. The LED of any of claims 18 to 24, further comprising a coating disposed over a surface of the wavelength converter that comprise at least one of a transparent film or a hazing film.
26. The LED of any of claims 18 to 25, wherein a surface of the pixelated LED comprises one or more etchings formed therein.
27. A photocurable ink composition, comprising:
   one or more photocurable polymers;
   a plurality of nanophosphors at least one of disposed within or on the one or more photocurable polymers; and
   one or more light-scattering additives at least one of disposed within or on the one or more photocurable polymers, the one or more light-scattering additives being configured to increase absorption of blue light.
28. The photocurable ink composition of claim 27, wherein an index of refraction is approximately greater than about 1.35.
29. The photocurable ink composition of claim 28, wherein the index of refraction is approximately in the range of about 1.35 to about 2.2.
30. The photocurable ink composition of any of claims 27 to 29, wherein the composition is configured such that it does not undergo phase separation during a photopolymerization process.
31. The photocurable ink composition of any of claims 27 to 30, wherein a concentration of the plurality of photopolymers is approximately in the range of about 25 mg/mL to about 50 mg/mL.
32. The photocurable ink composition of any of claims 27 to 31, wherein the plurality of nanophosphors comprises QDs.
33. The photocurable ink composition of claim 32, wherein the QDs comprise colloidal QDs.
34. The photocurable ink composition of any of claims 27 to 33, wherein the one or more light-scattering additives further comprise at least one of transparent oxides, alumina, undoped YAG, or BaSO₄.

1. A method of additively manufacturing an LED, comprising:
depositing a photocurable nanophosphor ink composition onto at least one of a substrate or a cured photocurable nanophosphor ink composition;
projecting a pattern onto at least one of the substrate, the cured photocurable nanophosphor ink composition, or the deposited photocurable nanophosphor ink composition; and
curing at least a portion of the photocurable nanophosphor ink composition based on the projected pattern.

2. The method of claim 1, further comprising:
depositing an additional photocurable nanophosphor ink composition onto at least one of the substrate or the cured photocurable nanophosphor ink composition;
projecting a second pattern onto at least one of the substrate, the cured photocurable nanophosphor ink composition, or the deposited photocurable nanophosphor ink composition;
curing at least a portion of the additional photocurable nanophosphor ink composition based on the projected second pattern; and
continuing to deposit, project, and cure until a three-dimensional LED having nanophosphors disposed therein is produced, the depositing being done with one or more further photocurable nanophosphor ink compositions and the projecting being done with one or more further patterns.

3. The method of claim 2, wherein the three-dimensional LED is configured to fully convert blue light-emitting pixels to at least one of red light-emitting pixels or green light-emitting pixels.

4. The method of claim 2, wherein pixels of the three-dimensional LED have a light-emitting pixel size that is approximately 25 μm or less.

5. The method of claim 4, wherein the light-emitting pixel size is approximately 10 μm or less.

6. (canceled)

7. The method of claim 2, wherein a distance between light-emitting pixels of the three-dimensional LED is approximately 5 μm or less.

8. The method of claim 2, wherein the three-dimensional LED comprises a plurality of square light-emitting pixels.

9. The method of claim 2, wherein a thickness of the three-dimensional LED is approximately in the range of about 2 μm to about 10 μm.

10. (canceled)

11. (canceled)

12. The method of claim 1, further comprising treating a surface of the substrate by at least one of chemically etching the surface, laser etching the surface, laser ablating the surface, or plasma activating the surface.

13. (canceled)

14. An additive manufacturing printing system, comprising:
a dispenser configured to deposit a photocurable nanophosphor ink composition onto at least one of a substrate or a cured photocurable nanophosphor ink composition;
a projector configured to project a pattern onto at least one of the substrate, the cured photocurable nanophosphor ink composition, or the deposited photocurable nanophosphor ink composition;
a light source configured to cure at least a portion of the photocurable nanophosphor ink composition based on the pattern projected by the projector; and
a controller configured to selectively operate each of the dispenser, the projector, and the light source to produce a three-dimensional LED that includes the substrate and the cured photocurable nanophosphor ink composition.

15. The system of claim 14, wherein the controller is configured to control the light source by controlling at least one of an exposure time and a power of the light source.

16. The system of claim 14, further comprising:
a stage on which the substrate is located,
wherein the controller is further configured to operate movement of the stage to locate the substrate at a desired location for at least one of receiving the photocurable nanophosphor ink composition from the dispenser, receiving the projected pattern from the projector, or receiving light from the light source to cure the photocurable nanophosphor ink composition.

17. The system of claim 14, further comprising a pass-through optic configured to at least allow light from the light source to be passed therethrough, towards the substrate.

18. An LED, comprising:
a pixelated LED having a plurality of individually addressable pixels configured to be controlled electrically for light emission; and
a wavelength converter deposited onto the pixelated LED, the wavelength converter comprising a plurality of nanophosphors, and the wavelength converter being configured to fully convert blue light-emitting pixels of the pixelated LED to at least one of red light-emitting pixels or green light-emitting pixels.

19. The LED of claim 18, wherein light-emitting pixels of the pixelated LED have a size that is approximately 25 μm or less.

20. The LED of claim 19, wherein the light-emitting pixel size is approximately 10 μm or less.

21. The LED of claim 20, wherein the light-emitting pixel size is approximately in the range of about 2 μm to about 5 μm.

22. The LED of claim 18, wherein a distance between light-emitting pixels of the pixelated LED is approximately 5 μm or less.

23. The LED of claim 18, wherein the pixelated LED comprises a plurality of square light-emitting pixels.

24. The LED of claim 18, wherein a thickness of the pixelated LED in combination with the wavelength converter is approximately in the range of about 2 μm to about 10 μm.

25-34. (canceled)
